(19) United States
(12) Patent Application Publication
(10) Pub. No.: US 2025/0343148 A1
(43) Pub. Date: Nov. 6, 2025

(54) INTEGRATED CHIP STRUCTURE WITH HIGH THERMAL CONDUCTIVITY LAYER

(71) Applicant: Taiwan Semiconductor Manufacturing Company, Ltd., Hsinchu (TW)

(72) Inventors: Ming-Hsien Lin, Hsinchu County (TW); Kun-Yen Liao, Taipei City (TW); Hsin-Ping Chen, Hsinchu County (TW); Chia-Tien Wu, Taichung City (TW); Hsiao-Kang Chang, Hsinchu City (TW)

(21) Appl. No.: 19/271,843

(22) Filed: Jul. 17, 2025

Related U.S. Application Data
(63) Continuation of application No. 18/419,915, filed on Jan. 23, 2024.
(60) Provisional application No. 63/594,076, filed on Oct. 30, 2023.

(51) Int. Cl. H01L 23/532; H01L 21/3213; H01L 23/427; H01L 23/528

(52) U.S. Cl. CPC H01L 23/53276; H01L 21/3213; H01L 23/427; H01L 23/528; H01L 23/53295

(57) ABSTRACT

The present disclosure relates to an integrated chip. The integrated chip includes a plurality of conductive interconnects arranged within a dielectric structure having a plurality of inter-level dielectric (ILD) layers stacked onto one another. A heat pipe vertically extends through the plurality of ILD layers. A high thermal conductivity layer is sandwiched between neighboring ones of the plurality of ILD layers. The high thermal conductivity layer laterally extends from over one or more of the plurality of conductive interconnects to the heat pipe.

### REFERENCE TO RELATED APPLICATIONS

This Application is a Continuation of U.S. application Ser. No. 18/419,915, filed on Jan. 23, 2024, which claims the benefit of U.S. Provisional Application No. 63/594,076, filed on Oct. 30, 2023. The contents of the above-referenced Patent Applications are hereby incorporated by reference in their entirety.

### BACKGROUND

Integrated chips are complex structures that include millions and/or billions of transistor devices disposed on a semiconductor body. The transistor devices are interconnected to one another and to passive devices (e.g., capacitors, inductors, etc.) by way of conductive interconnects disposed within a dielectric structure over the semiconductor body. During operation, the conductive interconnects are configured to selectively provide power to the devices, so as to cause them to perform a function.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip structure comprising a high thermal conductivity layer disposed along conductive interconnects within a dielectric structure.

FIG. 2 illustrates a cross-sectional view of some additional embodiments of an integrated chip structure comprising a high thermal conductivity layer disposed along conductive interconnects within a dielectric structure.

FIGS. 3A-3C illustrate cross-sectional views of some additional embodiments of integrated chip structures comprising a high thermal conductivity layer disposed along conductive interconnects at different positions within a dielectric structure.

FIGS. 4A-4C illustrate some additional embodiments of an integrated chip structure comprising a high thermal conductivity layer disposed along conductive interconnects within a dielectric structure.

FIGS. 5A-5D illustrate cross-sectional views of some additional embodiments of integrated chip structures comprising a high thermal conductivity layer disposed along conductive interconnects within a dielectric structure.

FIGS. 6A-6B illustrate some additional embodiments of an integrated chip structure comprising a high thermal conductivity layer disposed along conductive interconnects within a dielectric structure.

FIGS. 7A-7D illustrate top-views of some additional embodiments of an integrated chip structure comprising a high thermal conductivity layer within a dielectric structure having conductive interconnects.

FIG. 8 illustrates a cross-sectional view of some additional embodiments of a packaged integrated chip structure comprising a high thermal conductivity layer within a dielectric structure having conductive interconnects.

FIGS. 9-22 illustrate cross-sectional views of some embodiments corresponding to a method of forming an integrated chip structure comprising a high thermal conductivity layer within a dielectric structure having conductive interconnects.

FIG. 23 illustrates a flow diagram of some embodiments of a method of forming an integrated chip structure comprising a high thermal conductivity layer within a dielectric structure having conductive interconnects.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Conductive interconnects within an integrated chip structure are formed of a conductive material having a resistance. During operation, current flows through the conductive interconnects. The resistance of the conductive interconnects causes the current to generate heat due to Joule heating. The dissipation of heat in integrated circuits has become an increasing concern in recent years due to the miniaturization of semiconductor devices and/or conductive interconnects. This is at least in-part because as the size of the conductive interconnects decreases, the resistance of the conductive interconnects increases and the amount of heat generated due to Joule heating increases. Furthermore, to maintain good electrical isolation between the conductive interconnects, inter-level dielectric (ILD) materials having a low dielectric constant value are often used. Some ILD materials may even contain pores (e.g., air gaps) to decrease a dielectric constant value. However, ILD materials with a low dielectric constant and/or pores are poor conductors of heat (i.e., have a poor thermal conductivity).

An integrated chip structure with a poor thermal conductivity can lead to localized high on-chip temperatures and/or large temperature variations across the integrated chip structure. Large temperature variations may result in significant timing uncertainty and/or wide timing margins that can lead to poor circuit performance. For example, it has been appreciated that a timing delay degradation of about 5% occurs for every 20° C. of temperature variation. The temperature variations may also cause reliability concerns. For example, on-chip temperature gradients can produce mechanical stresses that lead to a degradation in integrated chip reliability.

The present disclosure relates to an integrated chip structure comprising a dielectric structure that surrounds a plurality of conductive interconnects and that comprises a laterally extending high thermal conductivity layer configured to enhance thermal diffusion along lateral directions and thereby avoid localized high temperature areas. In some embodiments, the integrated chip structure includes a dielectric structure comprising a plurality of inter-level dielectric (ILD) layers stacked onto one another over a substrate. A plurality of conductive interconnects are arranged within the plurality of ILD layers. A heat pipe vertically extends through the dielectric structure and a high thermal conductivity layer laterally extends through the dielectric structure from over one or more of the plurality of conductive interconnects to the heat pipe. Both the heat pipe and the high thermal conductivity layer have a higher thermal conductivity than the plurality of ILD layers. The higher thermal conductivity of the heat pipe and the high thermal conductivity layer provides for paths of both vertical and lateral heat diffusion, thereby allowing for heat to be efficiently transferred away from potential localized high temperature areas. By efficiently transferring heat away from potential localized high temperature areas, such high temperature areas can be avoided thereby increasing a performance and a reliability of an integrated chip structure. Therefore, the present disclosure combines vertical heat pipes and lateral high thermal conductivity layers to provide a highly efficient solution for dissipating heat in integrated chips.

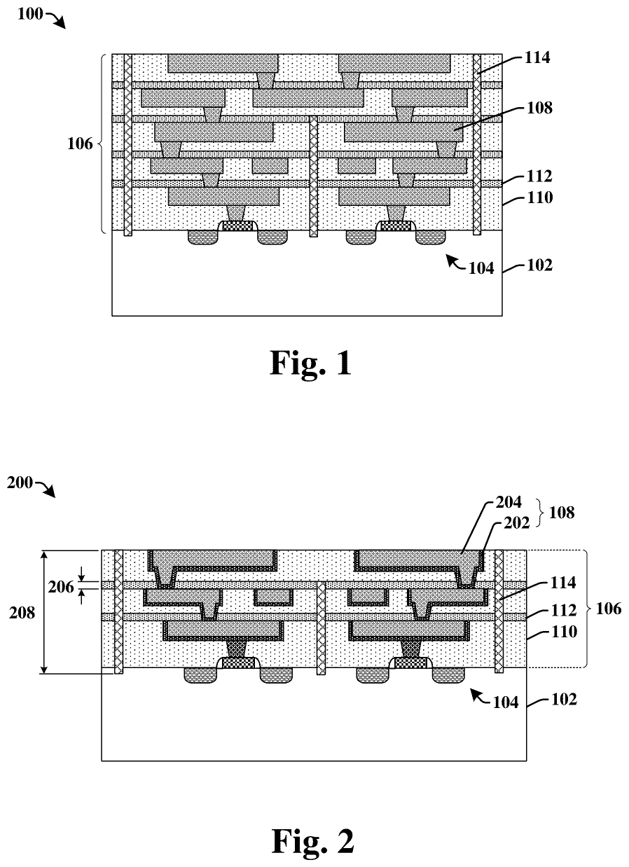

FIG. 1 illustrates a cross-sectional view of some embodiments of an integrated chip structure 100 comprising a high thermal conductivity layer disposed within a dielectric structure having conductive interconnects.

The integrated chip structure 100 includes a plurality of transistor devices 104 disposed within a substrate 102. A dielectric structure 106 is disposed over the substrate 102. The dielectric structure 106 surrounds a plurality of conductive interconnects 108, which are electrically coupled to the plurality of transistor devices 104. In some embodiments, the plurality of conductive interconnects 108 include conductive contacts, interconnect wires, and/or interconnect vias.

The dielectric structure 106 includes a plurality of inter-level dielectric (ILD) layers 110 stacked onto one another over the substrate 102. The plurality of ILD layers 110 may include low-k dielectric layers, ultra-low k dielectric layers, and/or the like. The plurality of ILD layers 110 respectively surround one or more of the plurality of conductive interconnects 108. In some embodiments, the plurality of conductive interconnects 108 vertically extend from a top of a surrounding ILD layer to within the surrounding ILD layer. The plurality of ILD layers 110 may have a thermal conductivity that is less than or equal to a first thermal conductivity.

The dielectric structure 106 further includes one or more high thermal conductivity layers 112. The one or more high thermal conductivity layers 112 laterally extend through the dielectric structure 106. In some embodiments, the one or more high thermal conductivity layers 112 are respectively arranged vertically between two neighboring ones of the plurality of ILD layers 110. In some embodiments, the one or more high thermal conductivity layers 112 laterally extend past the plurality of transistor devices 104. In some embodiments, the one or more high thermal conductivity layers 112 may laterally and continuously extend to outermost sidewalls of the plurality of ILD layers 110. The one or more high thermal conductivity layers 112 have a second thermal conductivity that is greater than the first thermal conductivity.

The dielectric structure 106 further includes one or more heat pipes 114. The one or more heat pipes 114 vertically extend through the dielectric structure 106. In some embodiments, the one or more heat pipes 114 vertically extend through one or more of the plurality of ILD layers 110 and the one or more high thermal conductivity layers 112. The one or more heat pipes 114 intersect at least one of the one or more high thermal conductivity layers 112. The one or more heat pipes 114 have a third thermal conductivity that is greater than the first thermal conductivity. Because the second and third thermal conductivities are greater than the first thermal conductivity, both the one or more high thermal conductivity layers 112 and the one or more heat pipes 114 have a greater ability to transfer heat than the plurality of ILD layers 110.

During operation, current running through the plurality of conductive interconnects 108 will cause the plurality of conductive interconnects 108 to generate heat. While the plurality of ILD layers 110 do not conduct heat well, a combination of the one or more high thermal conductivity layers 112 and the one or more heat pipes 114 are able to efficiently transfer heat and thereby dissipate heat from potential localized high temperature areas to surrounding areas. By dissipating heat from potential localized high temperature areas to surrounding areas, the one or more high thermal conductivity layers 112 and the one or more heat pipes 114 mitigate the formation of localized high temperature areas that could negatively impact a performance of the integrated chip structure 100 (e.g., due to timing uncertainty, wider timing margins, lower circuit performance, etc.) and/or compromise a reliability of the integrated chip structure 100 (e.g., due to mechanical stress caused by on-chip temperature variations).

FIG. 2 illustrates a cross-sectional view of some additional embodiments of an integrated chip structure 200 comprising a high thermal conductivity layer disposed within a dielectric structure having conductive interconnects.

The integrated chip structure 100 includes a plurality of transistor devices 104 disposed within a substrate 102. In various embodiments, the plurality of transistor devices 104 may comprise a planar FET, a FinFET, a gate all around structure, a nanowire structure, a CMOS BCD, a high voltage device, and/or the like. A dielectric structure 106 is disposed over the substrate 102. The dielectric structure 106 surrounds a plurality of conductive interconnects 108, which are electrically coupled to the plurality of transistor devices 104. In some embodiments, the plurality of conductive interconnects 108 may comprise conductive contacts configured to provide for vertical routing, interconnect wires configured to provide for lateral routing, and interconnect vias configured to provide for vertical routing. The interconnect wires may laterally extend past one or more sidewalls of a vertically adjacent interconnect via. In some embodiments, the plurality of conductive interconnects 108 may respectively comprise a conductive core 202 that is separated from the plurality of ILD layers 110 by a barrier layer 204. In some embodiments, the conductive core 202 may include a conductive material, such as tungsten, aluminum, copper, ruthenium, tantalum, titanium, or the like. In some embodiments, the barrier layer 204 may comprise a metal nitride, such as titanium nitride, tantalum nitride, and/or the like.

The dielectric structure 106 includes a plurality of ILD layers 110 stacked onto one another over the substrate 102. The plurality of ILD layers 110 respectively surround one or more of the plurality of conductive interconnects 108. In some embodiments, the plurality of ILD layers 110 may respectively comprise a nitride (e.g., silicon nitride, silicon oxynitride), a carbide (e.g., silicon carbide), an oxide (e.g., silicon oxide), borosilicate glass (BSG), phosphoric silicate glass (PSG), borophosphosilicate glass (BPSG), a low-k oxide (e.g., a carbon doped oxide, SiCOH), and/or the like. In some embodiments, one or more of the plurality of ILD layers 110 may include pores (e.g., air-gaps).

The dielectric structure 106 further includes one or more high thermal conductivity layers 112. The one or more high thermal conductivity layers 112 are respectively sandwiched vertically between two neighboring ones of the plurality of ILD layers 110. The one or more high thermal conductivity layers 112 are configured to enhance horizontal heat transfer within the dielectric structure 106. In some embodiments, the one or more high thermal conductivity layers 112 may be arranged along a top surface of an interconnect wire. In some embodiments, the one or more high thermal conductivity layers 112 continuously extend from along a top surface of a first interconnect wire to along a top surface of a second interconnect wire.

In some embodiments, the one or more high thermal conductivity layers 112 may comprise a material having a thermal conductivity (K) that is greater than approximately 1, that is greater than or equal to approximately 3, greater than or equal to approximately 10, greater than or equal to approximately 100, between approximately 3 and approximately 30, between approximately 20 and approximately 50, or other similar values. In some embodiments, the one or more high thermal conductivity layers 112 may comprise diamond (e.g., near isotropic diamond grains), boron nitride (BN), silicon carbide (SiC), beryllium oxide (BeO), boron phosphide (BP), aluminum nitride (AlN), beryllium sulfide (BeS), boron arsenide (BAs), gallium nitride (GaN), aluminum phosphide (AlP), gallium phosphide (GaP), aluminum oxide (Al₂O₃), graphene, and/or the like. In some embodiments, the one or more high thermal conductivity layers 112 may comprise poly-crystal SiC or single-crystal SiC, but not amorphous SiC, as amorphous SiC has a lower thermal conductivity than poly-crystal SiC or single-crystal SiC. In some embodiments, the one or more high thermal conductivity layers 112 may have a thickness 206 that is in a range of between approximately 0.01 microns (μm) and approximately 0.1 μm, between approximately 0.02 μm and approximately 0.03 μm, greater than approximately 0.5 μm, or other similar values.

In some embodiments, the one or more high thermal conductivity layers 112 are configured to operate as an etch stop layer or to be part of an etch stop structure. In such embodiments, the one or more high thermal conductivity layers 112 may comprise a material that is more resistant to etching than the plurality of ILD layers 110. For example, the one or more high thermal conductivity layers 112 may comprise a material that is etched at a lower rate than the plurality of ILD layers 110 during exposure to a dry etchant comprising fluorine, chlorine, and/or the like. In some embodiments, the plurality of conductive interconnects 108 have a bottom that is substantially aligned with a bottom of the one or more high thermal conductivity layers 112. In some embodiments, the one or more high thermal conductivity layers 112 may respectively have one or more surfaces that contact an adjacent one of the plurality of ILD layers 110. In some embodiments, the one or more high thermal conductivity layers 112 may continuously extend between a lower surface contacting an underlying one of the plurality of ILD layers 110 and an upper surface contacting an overlying one of the plurality of ILD layers 110.

The dielectric structure 106 further includes one or more heat pipes 114 vertically extending through one or more of the plurality of ILD layers 110 and the one or more high thermal conductivity layers 112. The one or more heat pipes 114 intersect at least one of the one or more high thermal conductivity layers 112. In some embodiments, the one or more heat pipes 114 vertically extend from the substrate 102 to a top of the dielectric structure 106. In such embodiments, the one or more heat pipes 114 have a height 208 that is greater than a height of the dielectric structure 106. In other embodiments, the one or more heat pipes 114 have a height 208 that is less than a height of the dielectric structure 106. In some embodiments, the one or more heat pipes 114 may comprise heat pipes having different heights (e.g., a first heat pipe having a first height, a second heat pipe having a second height that is different than the first height, etc.). In some embodiments, the one or more high thermal conductivity layers 112 continuously extend from along a top surface of a first interconnect wire to along a sidewall of the one or more heat pipes 114.

In some embodiments, the one or more heat pipes 114 may comprise a material having a thermal conductivity (K) that is greater than approximately 1, that is greater than or equal to approximately 3, or similar values. In some embodiments, the one or more heat pipes 114 may comprise diamond (e.g., near isotropic diamond grains), BN, SiC, BeO, BP, AlN, BeS, BAs, GaN, AlP, GaP, Al₂O₃, a graphene tube, and/or the like. In some embodiments, the one or more heat pipes 114 and the one or more high thermal conductivity layers 112 may comprise and/or be a same material. In other embodiments, the one or more heat pipes 114 and the one or more high thermal conductivity layers 112 may comprise and/or be different materials.

While the one or more heat pipes 114 enable a vertical diffusion of heat, each of the one or more heat pipes 114 consumes chip space, thereby reducing a density of the plurality of transistor devices 104. By using the one or more high thermal conductivity layers 112 to laterally transfer heat, the disclosed integrated chip structure can achieve a good diffusion of heat with a relatively small number of heat pipes thereby providing for efficient heat dissipation without consuming a large footprint.

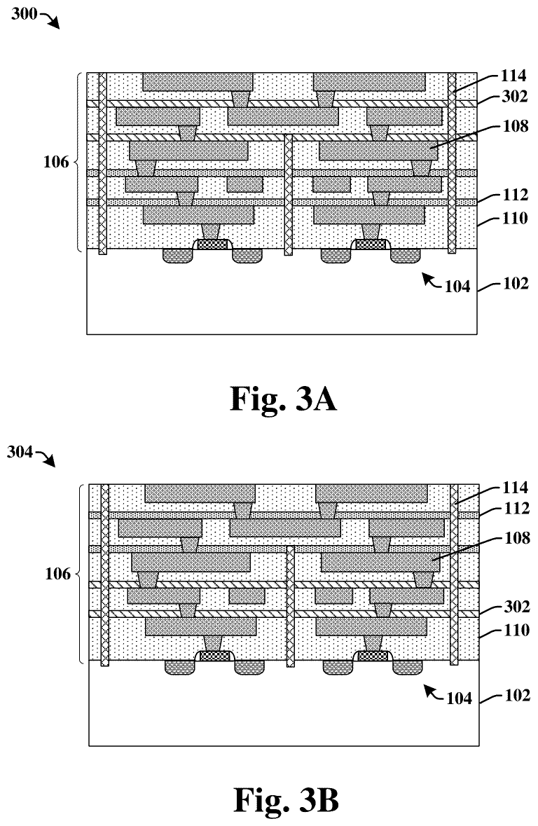

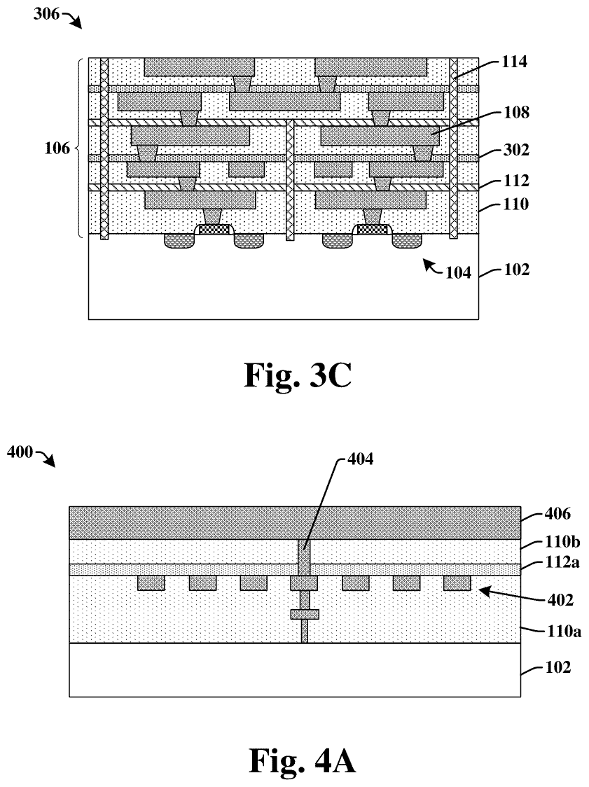

It will be appreciated that the disclosed high thermal conductivity layers can be disposed at different locations (e.g., at different vertical positions) within an integrated chip structure. For example, in various embodiments the disclosed thermal conductivity layers can be disposed within a BEOL (back-end-of-the-line) stack and/or FBEOL (far-back-end-of-the-line) (e.g., including redistribution layers and/or the like). FIGS. 3A-3C illustrates some embodiments of integrated chip structures that have thermal conductivity layers located within different locations within a BEOL.

FIG. 3A illustrates a cross-sectional view of some additional embodiments of an integrated chip structure 300 comprising a high thermal conductivity layer disposed along lower interconnect layers a dielectric structure having conductive interconnects.

The integrated chip structure 300 includes a plurality of transistor devices 104 disposed within a substrate 102. A dielectric structure 106 is disposed over the substrate 102. The dielectric structure 106 surrounds a plurality of conductive interconnects 108. The dielectric structure 106 includes a plurality of ILD layers 110 stacked onto one another over the substrate 102.

One or more high thermal conductivity layers 112 are respectively arranged between neighboring ones of the plurality of ILD layers 110. One or more etch stop layers 302 are also respectively arranged between neighboring ones of the plurality of ILD layers 110. In some embodiments, the one or more high thermal conductivity layers 112 include a plurality of high thermal conductivity layers and the one or more etch stop layers 302 include a plurality of etch stop layers above the plurality of high thermal conductivity layers. For example, in some embodiments the plurality of high thermal conductivity layers may be arranged on lower metal interconnect layers (e.g., M0, M1, M2, etc.) and not on higher metal interconnect layers (e.g., M6, M7, M8, etc.), while the plurality of etch stop layers may be arranged on the higher metal interconnect layers and not on the lower metal interconnect layers. In some embodiments, the plurality of high thermal conductivity layers may comprise a same material, while in other embodiments one or more of the plurality of high thermal conductivity layers may comprise different materials

One or more heat pipes 114 vertically extend through one or more of the plurality of ILD layers 110, the one or more high thermal conductivity layers 112, the one or more etch stop layers 302. The one or more heat pipes 114 intersect at least one of the one or more high thermal conductivity layers 112 and the one or more etch stop layers 302. In some embodiments, the one or more heat pipes 114 may have an uppermost surface that is substantially co-planar (e.g., co-planar within a tolerance of a chemical mechanical planarization (CMP) process) with an upper surface of one of the one or more high thermal conductivity layers 112 and/or an upper surface of one of the plurality of ILD layers 110.

FIG. 3B illustrates a cross-sectional view of some additional embodiments of an integrated chip structure 304 comprising a high thermal conductivity layer within a dielectric structure having conductive interconnects.

The integrated chip structure 304 includes one or more high thermal conductivity layers 112 respectively arranged between neighboring ones of a plurality of ILD layers 110. One or more etch stop layers 302 are also respectively arranged between neighboring ones of the plurality of ILD layers 110. In some embodiments, the one or more high thermal conductivity layers 112 may include a plurality of high thermal conductivity layers and the one or more etch stop layers 302 include a plurality of etch stop layers above the plurality of high thermal conductivity layers. In some embodiments, the plurality of high thermal conductivity layers may be arranged on higher metal interconnect layers (e.g., M6, M7, M8, etc.) and not on lower metal interconnect layers (e.g., M0, M1, M2, etc.), while the plurality of etch stop layers may be arranged on the lower metal interconnect layers and not on the higher metal interconnect layers. In some embodiments, the plurality of high thermal conductivity layers may be arranged on one or more of the topmost metal layers within a BEOL stack.

FIG. 3C illustrates a cross-sectional view of some additional embodiments of an integrated chip structure 306 comprising a high thermal conductivity layer within a dielectric structure having conductive interconnects.

The integrated chip structure 304 includes one or more high thermal conductivity layers 112 arranged between neighboring ones of a plurality of ILD layers 110. One or more etch stop layers 302 are also respectively arranged between neighboring ones of the plurality of ILD layers 110. In some embodiments, the dielectric stack vertically alternates between a high thermal conductivity layer and an etch stop layer. In some embodiments, a ILD layer may extend from a lower surface contacting a thermal conductivity layer to an upper surface contacting a high thermal conductivity layer or vice versa.

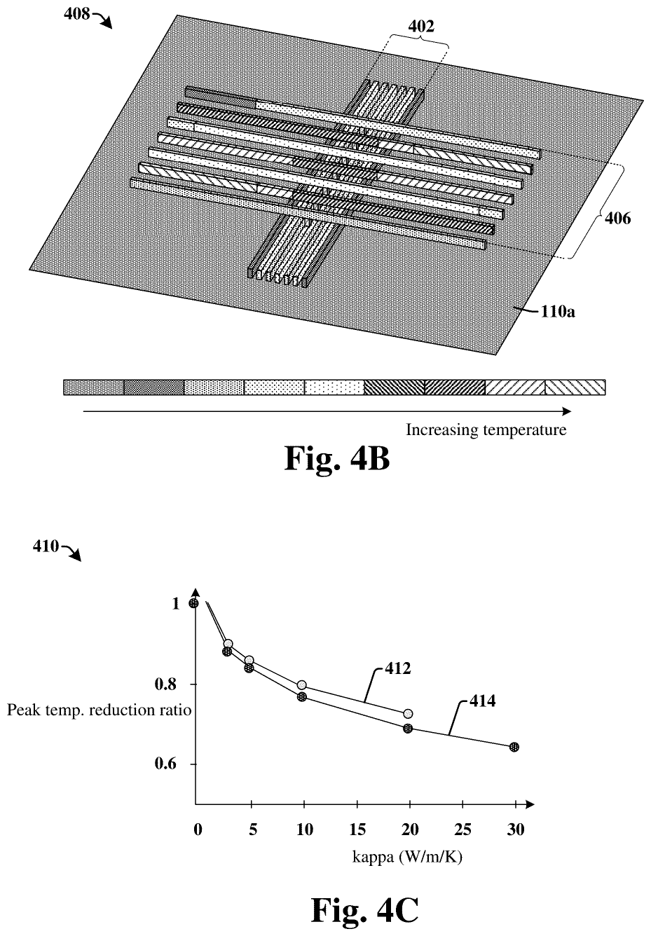

FIG. 4A illustrates a cross-sectional view of some additional embodiments of an integrated chip structure 400 comprising a high thermal conductivity layer within a dielectric structure having conductive interconnects.

The integrated chip structure 400 includes a first high thermal conductivity layer 112a arranged on a first plurality of interconnect wires 402 disposed within a first ILD layer 110a over a substrate 102. The first plurality of interconnect wires 402 are arranged on a same interconnect layer (e.g., at a same vertical height over the substrate 102). The first high thermal conductivity layer 112a continuously extends over the first plurality of interconnect wires 402. A first conductive via 404 is arranged within a second ILD layer 110b that is over the first ILD layer 110a. The first conductive via 404 vertically extends through the first high thermal conductivity layer 112a to contact one of the first plurality of interconnect wires 402. A second plurality of interconnect wires 406 are arranged over at least a part of the second ILD layer 110b.

FIG. 4B illustrates a three-dimensional view 408 showing different temperatures of the integrated chip structure during operation.

As can be seen in three-dimensional view 408, the first plurality of interconnect wires 402 remain at lower temperatures than the second plurality of interconnect wires 406. This is because the first high thermal conductivity layer (e.g., 112a of FIG. 4A) is in contact with upper surfaces of the first plurality of interconnect wires 402 and therefore allows for heat generated by the first plurality of interconnect wires 402 to be dissipated away from the first plurality of interconnect wires 402. Dissipating heat away from the first plurality of interconnect wires 402 reduces a maximum temperature of the first plurality of interconnect wires 402.

FIG. 4C illustrates a graph 410 showing a peak temperature reduction ratio as a function of thermal conductivity (Kappa value) for high thermal conductivity layers including a diamond film.

Graph 410 illustrates a peak temperature reduction ratio (e.g., a ratio of a peak temperature on the first plurality of interconnect wires to a temperature on the second plurality of interconnect wires) for high thermal conductivity layers having a first thickness 412 and a second thickness 414 that is larger than the first thickness 412. A peak temperature reduction ratio of less than 1 illustrates that the disclosed the high thermal conductivity layer is able to effectively dissipate heat. Furthermore, for both high thermal conductivity layers a peak temperature reduction ratio decreases as a thermal conductivity of the high thermal conductivity layer gets higher, thereby indicating that a higher thermal conductivity (Kappa value) improves heat dissipation. Furthermore, a peak temperature reduction ratio is consistently higher (e.g., denoting less temperature reduction) for the high thermal conductivity layer having the first thickness 412 than for the high thermal conductivity layers having the second thickness 414, thereby indicating that a larger thickness also improves heat dissipation.

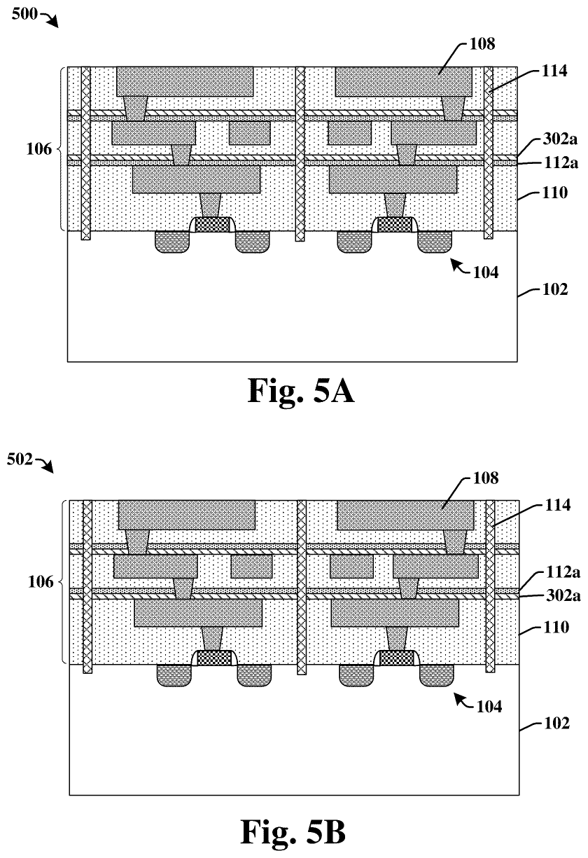

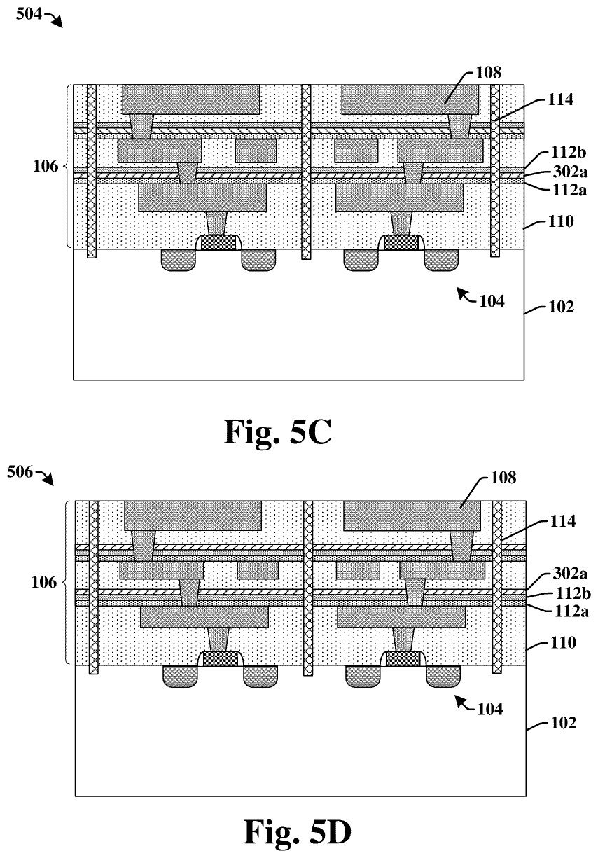

FIG. 5A illustrates a cross-sectional view of some additional embodiments of an integrated chip structure 500 comprising a high thermal conductivity layer within a dielectric structure having conductive interconnects.

The integrated chip structure 500 includes a dielectric structure 106 over a substrate 102. The dielectric structure 106 includes a plurality of ILD layers 110 stacked onto one another over the substrate 102. A first high thermal conductivity layer 112a and a first etch stop layer 302a are arranged between neighboring ones of the plurality of ILD layers 110. The first high thermal conductivity layer 112a and the first etch stop layer 302a may collectively operate as an etch stop structure. In some embodiments, the first high thermal conductivity layer 112a and the first etch stop layer 302a physically contact one another between the neighboring ones of the plurality of ILD layers 110. In some embodiments, the first high thermal conductivity layer 112a is below the first etch stop layer 302a.

FIG. 5B illustrates a cross-sectional view of some additional embodiments of an integrated chip structure 502 comprising a high thermal conductivity layer within a dielectric structure having conductive interconnects.

The integrated chip structure 502 includes a first high thermal conductivity layer 112a and a first etch stop layer 302a arranged vertically between neighboring ones of a plurality of ILD layers 110. The first high thermal conductivity layer 112a and the first etch stop layer 302a physically contact one another between the neighboring ones of the plurality of ILD layers 110. In some embodiments, the first high thermal conductivity layer 112a is above the first etch stop layer 302a.

FIG. 5C illustrates a cross-sectional view of some additional embodiments of an integrated chip structure 504 comprising a high thermal conductivity layer within a dielectric structure having conductive interconnects.

The integrated chip structure 504 includes a first high thermal conductivity layer 112a, a first etch stop layer 302a, and a second high thermal conductivity layer 112b arranged between neighboring ones of a plurality of ILD layers 110. The first high thermal conductivity layer 112a physically contacts a bottom surface of the first etch stop layer 302a between the neighboring ones of the plurality of ILD layers 110. The second high thermal conductivity layer 112b physically contacts a top surface of the first etch stop layer 302a between the neighboring ones of the plurality of ILD layers 110. The first high thermal conductivity layer 112a, the first etch stop layer 302a, and the second high thermal conductivity layer 112b may collectively operate as an etch stop structure. In some embodiments, the first high thermal conductivity layer 112a and the second high thermal conductivity layer 112b may be a same material. In other embodiments, the first high thermal conductivity layer 112a and the second high thermal conductivity layer 112b may be different materials.

FIG. 5D illustrates a cross-sectional view of some additional embodiments of an integrated chip structure 506 comprising a high thermal conductivity layer within a dielectric structure having conductive interconnects.

The integrated chip structure 506 includes a first high thermal conductivity layer 112a, a second high thermal conductivity layer 112b, and a first etch stop layer 302a arranged between neighboring ones of a plurality of ILD layers 110. The first high thermal conductivity layer 112a physically contacts a bottom surface of the second high thermal conductivity layer 112b between the neighboring ones of the plurality of ILD layers 110. The first etch stop layer 302a physically contacts a top surface of the second high thermal conductivity layer 112b between the neighboring ones of the plurality of ILD layers 110.

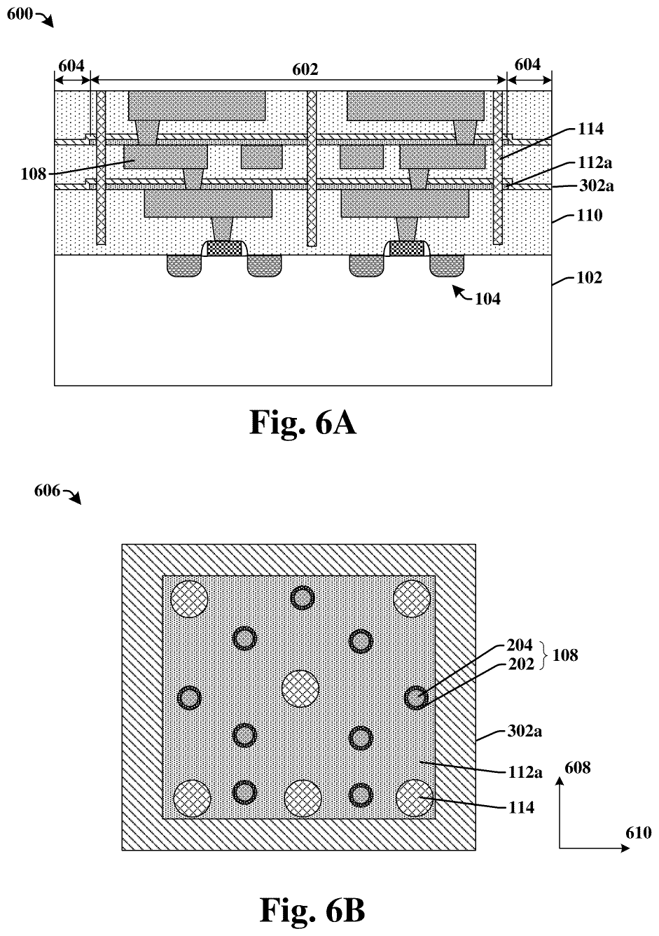

FIG. 6A illustrates a cross-sectional view of some additional embodiments of an integrated chip structure 600 comprising a high thermal conductivity layer within a dielectric structure having conductive interconnects.

The integrated chip structure 600 includes a first high thermal conductivity layer 112a and a first etch stop layer 302a arranged between neighboring ones of a plurality of ILD layers 110. The first high thermal conductivity layer 112a and the first etch stop layer 302a physically contact one another between the neighboring ones of the plurality of ILD layers 110. In some embodiments, the first high thermal conductivity layer 112a and the first etch stop layer 302a physically contact one another along an interface that laterally extends between one or more heat pipes 114.

In some embodiments, the first high thermal conductivity layer 112a is confined to within a first region 602 of the integrated chip structure 600. In such embodiments, the first high thermal conductivity layer 112a and the first etch stop layer 302a physically contact one another within the first region 602 of the integrated chip structure 600, but not within a second region 604 of the integrated chip structure 600. In some embodiments, the first region 602 may comprise a high-power region (e.g., a region comprising devices that utilize a relatively high power and/or current that may generate a larger amount of heat through Joule heating) and the second region 604 may comprise a lower power region (e.g., a region comprising devices that utilize a lower power and/or current than the devices within the first region 602).

FIG. 6B illustrates a top-view 606 of some additional embodiments of the integrated chip structure of FIG. 6A. As shown in top-view 606, the first etch stop layer 302a laterally surrounds the first high thermal conductivity layer 112a along a first direction 608 and along a second direction 610 that is perpendicular to the first direction 608.

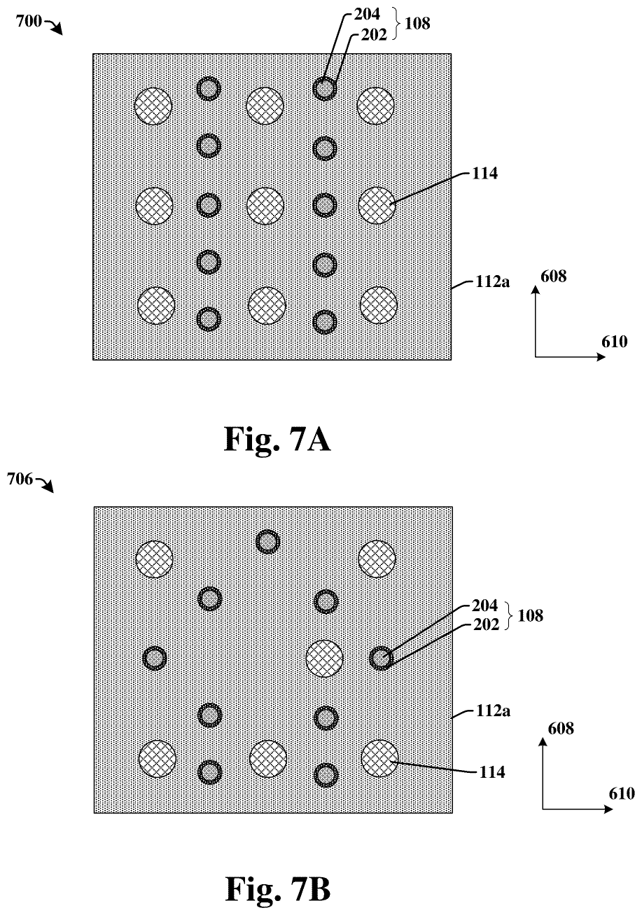

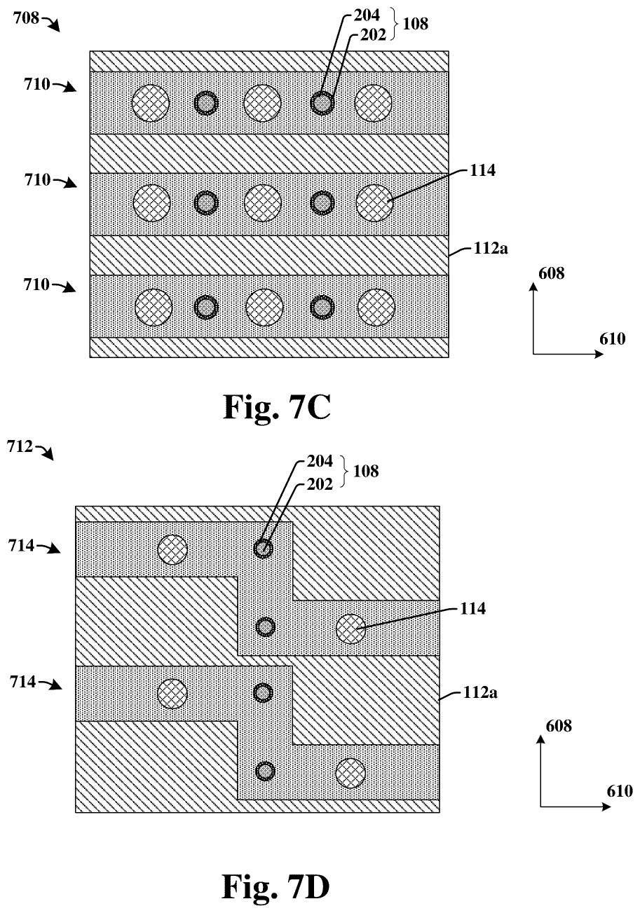

FIG. 7A illustrates a top-view 700 of some additional embodiments of an integrated chip structure comprising a high thermal conductivity layer within a dielectric structure having conductive interconnects.

As shown in top-view 700, a first high thermal conductivity layer 112a extends over a substrate (not shown) in a first direction 608 and in a second direction 610 that is perpendicular to the first direction 608. A plurality of conductive interconnects 108 (e.g., interconnect vias) extend through the first high thermal conductivity layer 112a. The plurality of conductive interconnects 108 are separated from one another by the first high thermal conductivity layer 112a along the first direction 608 and along the second direction 610. One or more heat pipes 114 also extend through the first high thermal conductivity layer 112a. The one or more heat pipes 114 are separated from one another by the first high thermal conductivity layer 112a along the first direction 608 and along the second direction 610.

In some embodiments, the one or more heat pipes 114 may be arranged in a periodic pattern (e.g., an array extending in the first direction 608 and the second direction 610). Having the one or more heat pipes 114 arranged in a periodic pattern may improve heat dissipation. In other embodiments (e.g., as shown in top-view 706 of FIG. 7B), the one or more heat pipes 114 may be arranged in a non-periodic pattern. Having the one or more heat pipes 114 arranged in a non-periodic pattern may improve routing flexibility.

Because the one or more heat pipes 114 are separated from one another by the high thermal conductivity layer 112 along the first direction 608 and along the second direction 610, the first high thermal conductivity layer 112a is able to conduct heat along the first direction 608 and along the second direction 610, thereby efficiency dissipating heat.

FIG. 7C illustrates a top-view 708 of some additional embodiments of an integrated chip structure comprising a high thermal conductivity layer within a dielectric structure having conductive interconnects.

As shown in top-view 708, a first high thermal conductivity layer 112a extends over the substrate (not shown) as a plurality of rectangular strips 710. The plurality of rectangular strips 710 intersect one or more heat pipes 114, so that the plurality of rectangular strips 710 are able to transfer heat laterally over the substrate to the one or more heat pipes 114. In some embodiments, the plurality of rectangular strips 710 respectively have a width extending in a first direction 608 and a length extending in a second direction 610 that is perpendicular to the first direction 608. The length is larger than the width.

FIG. 7D illustrates a top-view 712 of some additional embodiments of an integrated chip structure comprising a high thermal conductivity layer within a dielectric structure having conductive interconnects.

As shown in top-view 712, a first high thermal conductivity layer 112a extends over the substrate (not shown) as a plurality of polygonal shaped segments 714 that have regions extending in a first direction 608 and in a second direction 610. The plurality of polygonal shaped segments 714 intersect one or more heat pipes 114, so that the plurality of polygonal shaped segments 714 are able to transfer heat laterally over the substrate to the one or more heat pipes 114.

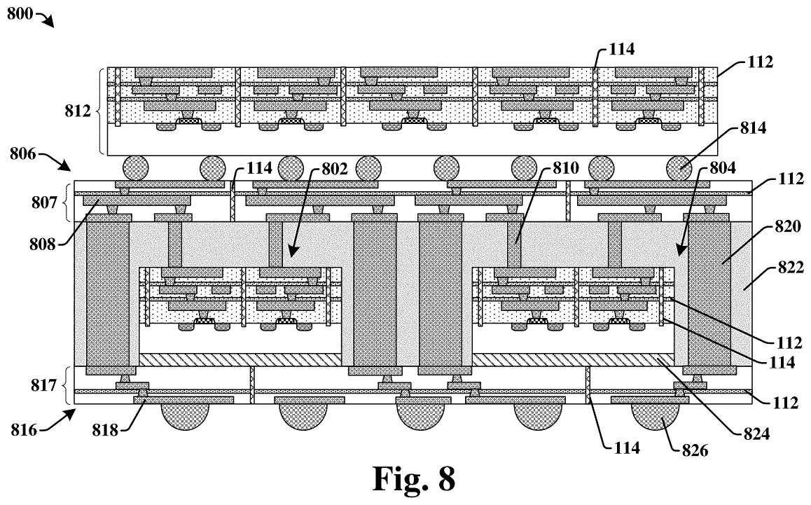

FIG. 8 illustrates a cross-sectional view of some additional embodiments of a packaged integrated chip structure 800 comprising a high thermal conductivity layer within a dielectric structure having conductive interconnects

The packaged integrated chip structure 800 comprises a plurality of IC die 802-804 (e.g., chiplets). In some embodiments, the plurality of IC die 802-804 may respectively include a dielectric structure disposed over a substrate and surrounding a plurality of conductive interconnects. The dielectric structure may include one or more high thermal conductivity layers 112 laterally extending through the dielectric structure and one or more heat pipes vertically extending through the dielectric structure 106.

The plurality of IC die 802-804 are disposed between an upper redistribution structure 806 and a lower redistribution structure 816. In some embodiments, the plurality of IC die 802-804 may be coupled to the lower redistribution structure 816 by way of an adhesive 824. The upper redistribution structure 806 comprises a plurality of upper redistribution layers 808 disposed within an upper dielectric structure 807. In some embodiments, the upper dielectric structure 807 includes one or more high thermal conductivity layers 112 laterally extending through the upper dielectric structure 807 and one or more heat pipes 114 vertically extending through the upper dielectric structure 807. The lower redistribution structure 816 comprises a plurality of lower redistribution layers 818 disposed within a lower dielectric structure 817. In some embodiments, the lower dielectric structure 817 includes one or more high thermal conductivity layers 112 laterally extending through the lower dielectric structure 817 and one or more heat pipes 114 vertically extending through the lower dielectric structure 817.

The plurality of IC die 802-804 are electrically coupled to the plurality of upper redistribution layers 808 by conductive structures 810 over the plurality of IC die 802-804. The plurality of upper redistribution layers 808 are coupled to an overlying IC die 812 by way of a plurality of conductive bumps 814 (e.g., micro-bumps). The plurality of upper redistribution layers 808 are further coupled to the plurality of lower redistribution layers 818 by way of one or more conductive bonding structures 820 (e.g., copper posts). The plurality of lower redistribution layers 818 are further coupled to a plurality of solder bumps 826. In some embodiments, a molding compound 822 is also disposed over the lower redistribution structure 816 and surrounds the plurality of IC die 802-804 and the one or more conductive bonding structures 820.

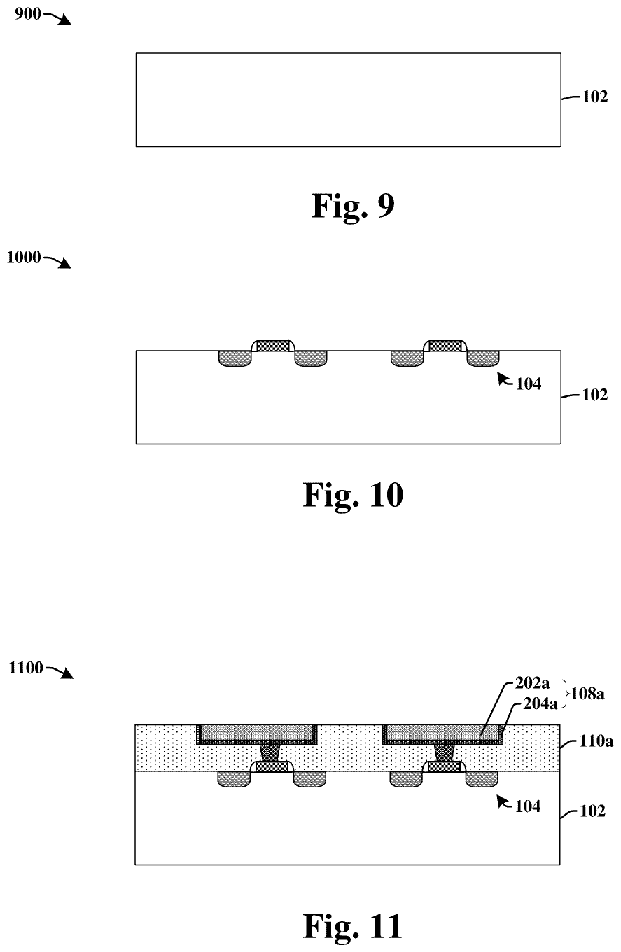

FIGS. 9-22 illustrate cross-sectional views 900-2200 of some embodiments corresponding to a method of forming an integrated chip structure comprising a high thermal conductivity layer within a dielectric structure having conductive interconnects. Although FIGS. 9-22 are described in relation to a method, it will be appreciated that the structures disclosed in the method are not limited to the method, but instead may stand alone as structures independent of the method.

As shown in cross-sectional view 900 of FIG. 9, a substrate 102 is provided. In various embodiments, the substrate 102 may be any type of semiconductor body (e.g., silicon, SiGe, etc.), such as a semiconductor wafer and/or one or more die on a wafer, as well as any other type of semiconductor and/or epitaxial layers, associated therewith. In some embodiments, the substrate 102 may comprise a p-type doping.

As shown in cross-sectional view 1000 of FIG. 10, a plurality of transistor devices 104 are formed on and/or within the substrate 102. In some embodiments, the plurality of transistor devices 104 may be formed by forming a gate dielectric layer over the substrate 102 and forming a gate electrode layer over the gate dielectric layer. In some embodiments, the gate dielectric layer may be formed by a deposition process (e.g., physical vapor deposition (PVD), chemical vapor deposition (CVD), plasma enhanced CVD (PE-CVD), atomic layer deposition (ALD), etc.) and/or a thermal process. In some embodiments, the gate electrode layer may be formed by a deposition process. The gate dielectric layer and the gate electrode layer are subsequently patterned to form a plurality of gate structures. In some embodiments, the gate dielectric layer and the gate electrode layer may be patterned according to one or more patterning processes that use a photolithography process to form a mask (e.g., a photosensitive material, a hard mask, or the like) over the gate electrode layer and that subsequently expose the gate dielectric layer and the gate electrode layer to one or more etchants according to the mask.

As shown in cross-sectional view 1100 of FIG. 11, a first ILD layer 110a is formed over the substrate 102. The first ILD layer 110a covers the plurality of transistor devices 104. In some embodiments, the first ILD layer 110a may comprise a nitride (e.g., silicon nitride, silicon oxynitride), a carbide (e.g., silicon carbide), an oxide (e.g., silicon oxide), BSG, PSG, BPSG, a low-k oxide (e.g., a carbon doped oxide, SiCOH), a porous dielectric material, and/or the like. In some embodiments, the first ILD layer 110a may be formed by way of a deposition process (e.g., PVD, CVD, PE-CVD, ALD, sputtering, etc.).

A first interconnect 108a is formed within the first ILD layer 110a. In some embodiments, the first interconnect 108a may be formed using a damascene process (e.g., a single damascene process or a dual damascene process). The damascene process is performed by etching the first ILD layer 110a to form a hole and/or a trench, and filling the hole and/or trench with a liner and/or conductive material. In some embodiments, the conductive material may be formed using a deposition process and/or a plating process (e.g., electroplating, electro-less plating, etc.). In various embodiments, the first interconnect 108a may comprise tungsten, copper, aluminum, tungsten, ruthenium, and/or the like. After filling the hole and/or trench with a liner and/or conductive material, a planarization process (e.g., a chemical mechanical planarization (CMP) process) may be performed to remove excess of the conductive material and/or liner from over the first ILD layer 110a.

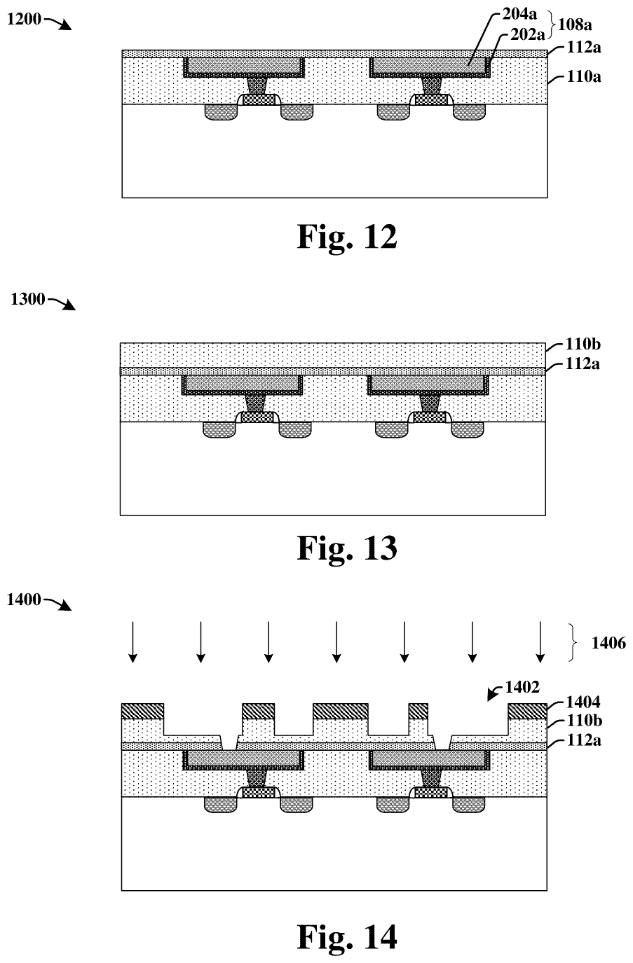

As shown in cross-sectional view 1200 of FIG. 12, a first high thermal conductivity layer 112a is formed over the first ILD layer 110a. In some embodiments, the first high thermal conductivity layer 112a may be formed by way of a deposition process (e.g., PVD, CVD, PE-CVD, ALD, sputtering, etc.). In some embodiments, the first high thermal conductivity layer 112a may comprise diamond (e.g., near isotropic diamond grains), BN, SiC (e.g., poly-crystal SiC or single-crystal SiC), BeO, BP, AlN, BeS, BAs, GaN, AlP, GaP, Al₂O₃, graphene, and/or the like. In some embodiments, the first high thermal conductivity layer 112a may be formed to have a thickness 206 that is in a range of between approximately 0.01 microns (μm) and approximately 0.1 μm, between approximately 0.02 μm and approximately 0.03 μm, or other similar values. In some embodiments, the first high thermal conductivity layer 112a may be formed by a deposition process performed at a temperature of less than or equal to approximately 450° C.

As shown in cross-sectional view 1300 of FIG. 13, a second ILD layer 110b is formed over the first high thermal conductivity layer 112a. In some embodiments, the second ILD layer 110b may comprise a nitride (e.g., silicon nitride, silicon oxynitride), a carbide (e.g., silicon carbide), an oxide (e.g., silicon oxide), BSG, PSG, BPSG, a low-k oxide (e.g., a carbon doped oxide, SiCOH), a porous dielectric material, and/or the like. In some embodiments, the second ILD layer 110b may be formed by way of a deposition process.

As shown in cross-sectional view 1400 of FIG. 14, one or more second interconnect openings 1402 are formed within the second ILD layer 110b. In some embodiments, the one or more second interconnect openings 1402 may be formed by forming a mask 1404 over the second ILD layer 110b. The second ILD layer 110b and the first high thermal conductivity layer 112a are subsequently patterned according to the mask 1404 to form the one or more second interconnect openings 1402. In some embodiments, the second ILD layer 110b and the first high thermal conductivity layer 112a are patterned by exposing the second ILD layer 110b and the first high thermal conductivity layer 112a to one or more etchants 1406 in areas not covered by the mask 1404. In some embodiments, the one or more etchants 1406 may be selected to have a high etching selectivity between the second ILD layer 110b and the first high thermal conductivity layer 112a. For example, the one or more etchants 1406 may be selected to etch the second ILD layer 110b at a higher etching rate than the first high thermal conductivity layer 112a. Selecting the one or more etchants 1406 to have a high etching selectivity between the second ILD layer 110b and the first high thermal conductivity layer 112a allows for the first high thermal conductivity layer 112a to act as an etch stop layer, thereby saving the cost and time of depositing a separate etch stop layer.

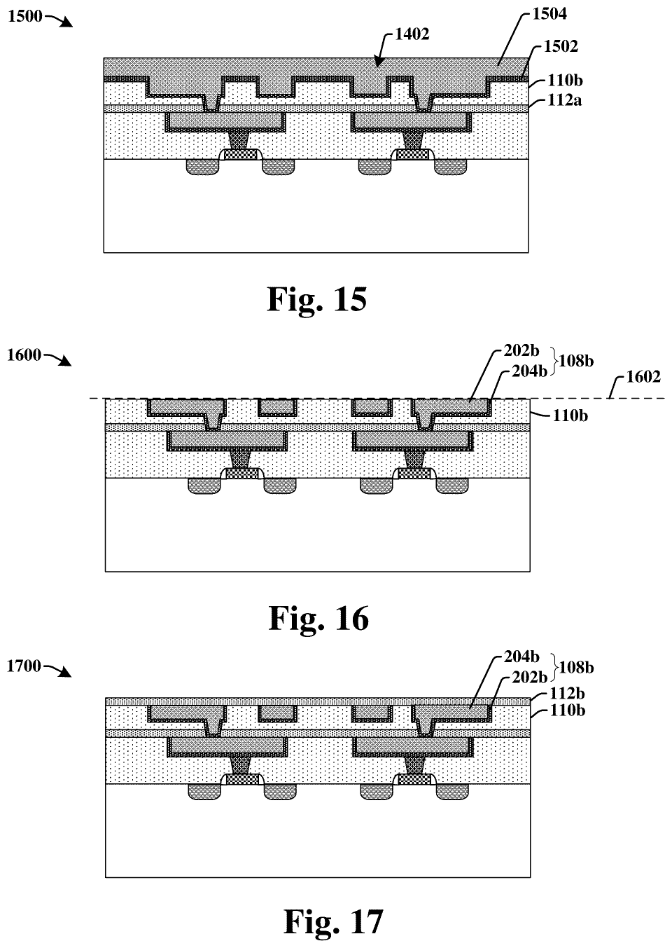

As shown in cross-sectional view 1500 of FIG. 15, the one or more second interconnect openings 1402 are filled with a liner 1502 and a conductive material 1504. In some embodiments, the liner 1502 may be formed using a deposition process. In some embodiments, the conductive material 1504 may be formed using a deposition process and/or a plating process. In some embodiments, the liner may comprise a metal (e.g., titanium, tantalum, etc.), a metal nitride (e.g., titanium nitride, tantalum nitride, etc.), and/or the like. In some embodiments, the conductive material 1504 may comprise tungsten, copper, aluminum, and/or the like.

As shown in cross-sectional view 1600 of FIG. 16, after filling the one or more second interconnect openings (e.g., 1402 of FIG. 15) with a liner (e.g., 1502 of FIG. 15) and/or conductive material (e.g., 1504 of FIG. 15), a planarization process (e.g., a CMP process) may be performed (e.g., along line 1602) to remove excess of the conductive material and/or liner from over the second ILD layer 110b. Removing excess of the conductive material and/or liner forms a second interconnect 108b having a conductive core 202b surrounded by a barrier layer 204b. The second interconnect 108b extends along sidewalls of the second ILD layer 110b and the first high thermal conductivity layer 112a.

As shown in cross-sectional view 1700 of FIG. 17, a second high thermal conductivity layer 112b is formed over the second ILD layer 110b. In some embodiments, the second high thermal conductivity layer 112b may be formed by way of a deposition process (e.g., PVD, CVD, PE-CVD, ALD, sputtering, etc.). In some embodiments, the second high thermal conductivity layer 112b may comprise diamond, BN, SiC, BeO, BP, AlN, BeS, Bas, GaN, AlP, GaP, Al2O3, graphene, and/or the like. In some embodiments, the second high thermal conductivity layer 112b may be formed to have a thickness that is in a range of between approximately 0.01 μm and approximately 0.1 μm, between approximately 0.02 μm and approximately 0.03 μm, or other similar values. In some embodiments, the first high thermal conductivity layer (e.g., 112a of FIG. 12) and the second high thermal conductivity layer 112b may comprise and/or be a same material. In other embodiments, the first high thermal conductivity layer (e.g., 112a of FIG. 12) and the second high thermal conductivity layer 112b may comprise and/or be a different materials. In some embodiments, the second high thermal conductivity layer 112b may be formed by a deposition process performed at a temperature of less than or equal to approximately 450° C.

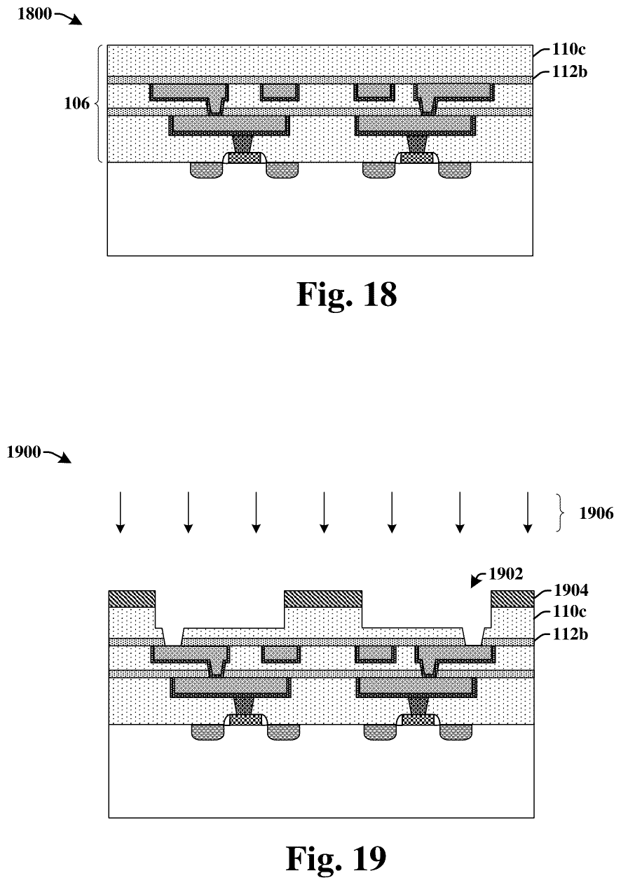

As shown in cross-sectional view 1800 of FIG. 18, a third ILD layer 110c is formed over the second high thermal conductivity layer 112b. In some embodiments, the third ILD layer 110c may comprise a nitride (e.g., silicon nitride, silicon oxynitride), a carbide (e.g., silicon carbide), an oxide (e.g., silicon oxide), BSG, PSG, BPSG, a low-k oxide (e.g., a carbon doped oxide, SiCOH), a porous dielectric material, and/or the like. In some embodiments, the third ILD layer 110c may be formed by way of a deposition process. In some embodiments, the third ILD layer 110c may comprise a top ILD layer of a dielectric structure 106.

As shown in cross-sectional view 1900 of FIG. 19, one or more third interconnect openings 1902 are formed within the third ILD layer 110c. In some embodiments, the one or more third interconnect openings 1902 may be formed by forming a mask 1904 over the third ILD layer 110c. The third ILD layer 110c and the second high thermal conductivity layer 112b are subsequently patterned according to the mask 1904 to form the one or more third interconnect openings 1902. In some embodiments, the third ILD layer 110c and the second high thermal conductivity layer 112b are patterned by exposing the third ILD layer 110c and the second high thermal conductivity layer 112b to one or more etchants 1906 in areas not covered by the mask 1904. In some embodiments, the one or more etchants may be selected to have a high etching selectivity between the third ILD layer 110c and the second high thermal conductivity layer 112b. For example, the one or more etchants 1906 may be selected to etch the third ILD layer 110c at a higher etching rate than the second high thermal conductivity layer 112b. Selecting the one or more etchants to have a high etching selectivity between the third ILD layer 110c and the second high thermal conductivity layer 112b allows for the second high thermal conductivity layer 112b to act as an etch stop layer, thereby saving the cost and time of depositing a separate etch stop layer.

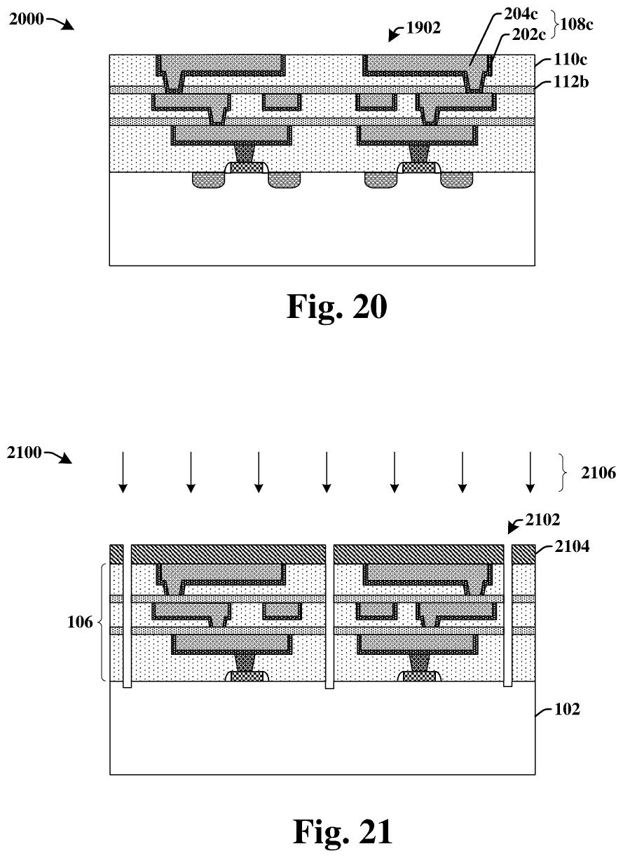

As shown in cross-sectional view 2000 of FIG. 20, a third interconnect 108c may be formed within the one or more third interconnect openings 1902. The third interconnect 108c extends along sidewalls of the third ILD layer 110c and the second high thermal conductivity layer 112b. In some embodiments, the third interconnect 108c may be formed by filling the one or more third interconnect openings 1902 with a liner and a conductive material. After the one or more third interconnect openings 1902 with a liner and/or conductive material, a planarization process (e.g., a CMP process) may be performed to remove excess of the conductive material from over the third ILD layer 110c.

As shown in cross-sectional view 2100 of FIG. 21, one or more heat pipe openings 2102 are formed within the dielectric structure 106. In some embodiments, the one or more heat pipe openings 2102 may vertically extend from a top of the dielectric structure 106 to the substrate 102. In other embodiments (not shown), the one or more heat pipe openings 2102 may vertically extend from a top of the dielectric structure 106 to above the substrate 102. In some embodiments, the one or more heat pipe openings 2102 may be formed by forming a mask 2104 over the dielectric structure 106. The dielectric structure 106 is subsequently exposed to one or more etchants 2106 according to the mask 2104 to form the one or more heat pipe openings 2102.

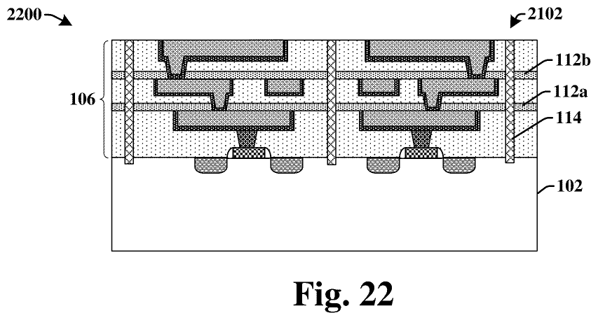

As shown in cross-sectional view 2200 of FIG. 22, one or more heat pipes 114 are formed within the one or more heat pipe openings 2102 within the dielectric structure 106. The one or more heat pipes 114 vertically extend through the dielectric structure 106. In some embodiments, the one or more heat pipes 114 may be formed by depositing a material with a high thermal conductivity within the one or more heat pipe openings 2102. In some embodiments, the high thermal conductivity may be formed using a deposition process. After filling the one or more heat pipe openings 2102 with the high thermal conductivity, a planarization process (e.g., a CMP process) may be performed to remove excess of the high thermal conductivity from over the dielectric structure 106.

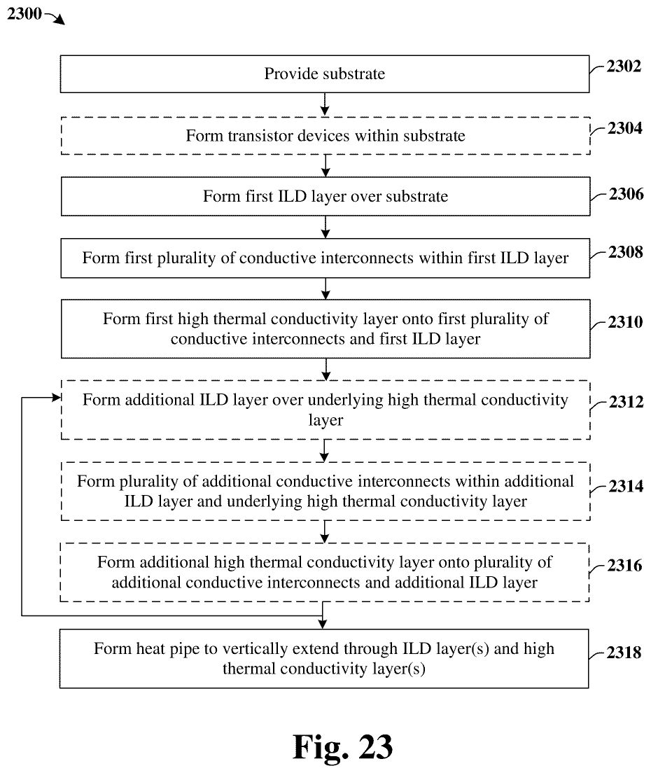

FIG. 23 illustrates a flow diagram of some embodiments of a method 2300 of forming an integrated chip structure comprising a high thermal conductivity layer within a dielectric structure having conductive interconnects.

While method 2300 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2302, a substrate is provided. FIG. 9 illustrates a cross-sectional view 900 of some embodiments corresponding to act 2302.

At act 2304, a plurality of transistor devices may be formed within the substrate. FIG. 10 illustrates a cross-sectional view 1000 of some embodiments corresponding to act 2304.

At act 2306, a first ILD layer is formed over the substrate. FIG. 11 illustrates a cross-sectional view 1100 of some embodiments corresponding to act 2306.

At act 2308, a first plurality of conductive interconnects are formed within the first ILD layer. FIG. 11 illustrates a cross-sectional view 1100 of some embodiments corresponding to act 2308.

At act 2310, a first high thermal conductivity layer is formed over the first plurality of conductive interconnects and the first ILD layer. FIG. 12 illustrates a cross-sectional view 1200 of some embodiments corresponding to act 2310.

At act 2312, an additional ILD layer may be formed over an underlying high thermal conductivity layer (e.g., the first high thermal conductivity layer). FIG. 13 illustrates a cross-sectional view 1300 of some embodiments corresponding to act 2312.

At act 2314, a plurality of additional conductive interconnects may be formed within the additional ILD layer and the underlying high thermal conductivity layer. FIGS. 14-16 illustrate cross-sectional views 1400-1600 of some embodiments corresponding to act 2314.

At act 2316, an additional high thermal conductivity layer may be formed onto the plurality of additional conductive interconnects and the additional ILD layer. FIG. 17 illustrates a cross-sectional view 1700 of some embodiments corresponding to act 2316.

It will be appreciated that one or more of acts 2312-2316 may be iteratively repeated to form a plurality of conductive interconnect layers stacked onto one another.

At act 2318, a heat pipe is formed to vertically extend through one or more ILD layers and one or more high thermal conductivity layers. FIGS. 21-22 illustrate cross-sectional views 2100-2200 of some embodiments corresponding to act 2318.

Accordingly, the present disclosure relates to an integrated chip structure comprising a dielectric structure that surrounds a plurality of conductive interconnects and that comprises a laterally extending high thermal conductivity layer configured to enhance thermal diffusion along lateral directions and thereby avoid localized high temperature areas.

In some embodiments, the present disclosure relates to an integrated chip structure. The integrated chip structure includes a plurality of conductive interconnects arranged within a dielectric structure having a plurality of inter-level dielectric (ILD) layers stacked onto one another; a heat pipe vertically extending through the plurality of ILD layers; and a high thermal conductivity layer sandwiched between neighboring ones of the plurality of ILD layers, the high thermal conductivity layer laterally extending from over one or more of the plurality of conductive interconnects to the heat pipe. In some embodiments, the heat pipe vertically extends through the high thermal conductivity layer. In some embodiments, the plurality of conductive interconnects include an interconnect wire and an interconnect via contacting an upper surface of the interconnect wire; the high thermal conductivity layer extending along the upper surface of the interconnect wire and along opposing sidewalls of the interconnect via. In some embodiments, the high thermal conductivity layer has a thermal conductivity of greater than or equal to approximately 3. In some embodiments, the high thermal conductivity layer includes one or more of diamond, boron nitride, silicon carbide, beryllium oxide, boron phosphide, aluminum nitride, beryllium sulfide, boron arsenide, gallium nitride, aluminum phosphide, gallium phosphide, aluminum oxide, and graphene. In some embodiments, the integrated chip structure further includes an etch stop layer arranged between the neighboring ones of the plurality of ILD layers, the etch stop layer contacting the high thermal conductivity layer along an interface that laterally extends from over one or more of the plurality of conductive interconnects to the heat pipe. In some embodiments, the etch stop layer contacts a top surface of the high thermal conductivity layer. In some embodiments, the etch stop layer contacts a bottom surface of the high thermal conductivity layer. In some embodiments, the integrated chip structure further includes a second high thermal conductivity layer arranged between the neighboring ones of the plurality of ILD layers, the second high thermal conductivity layer contacting the high thermal conductivity layer along an interface that laterally extends from over one or more of the plurality of conductive interconnects to the heat pipe; the high thermal conductivity layer and the second high thermal conductivity layer including different materials.

In other embodiments, the present disclosure relates to an integrated chip structure. The integrated chip structure includes a dielectric structure having a plurality of inter-level dielectric (ILD) layers stacked onto one another over a substrate, the plurality of ILD layers respectively having a thermal conductivity that is less than or equal to a first thermal conductivity; a plurality of interconnects arranged within the plurality of ILD layers; a heat pipe vertically extending through the dielectric structure, the heat pipe having a second thermal conductivity that is larger than the first thermal conductivity; and a high thermal conductivity layer laterally extending through the dielectric structure from over one or more of the plurality of interconnects to the heat pipe, the high thermal conductivity layer having a third thermal conductivity that is larger than the first thermal conductivity. In some embodiments, the high thermal conductivity layer includes diamond grains. In some embodiments, the integrated chip structure further includes a second high thermal conductivity layer laterally extending through the dielectric structure from over one or more of the plurality of interconnects to the heat pipe, the second high thermal conductivity layer being a different material than the high thermal conductivity layer. In some embodiments, the integrated chip structure further includes an etch stop layer laterally extending through the dielectric structure, the etch stop layer having a lower thermal conductivity than the high thermal conductivity layer. In some embodiments, the high thermal conductivity layer is more resistant to etching than the plurality of ILD layers.

In yet other embodiments, the present disclosure relates to a method of forming an integrated chip structure. The method includes forming a first interconnect within a first ILD layer over a substrate; depositing a high thermal conductivity layer on the first interconnect and the first ILD layer, the high thermal conductivity layer having a greater thermal conductivity than the first ILD layer; etching the high thermal conductivity layer and the first ILD layer to form a heat pipe opening; and forming a heat pipe within the heat pipe opening, the heat pipe having a greater thermal conductivity than the first ILD layer. In some embodiments, the high thermal conductivity layer has a thermal conductivity of greater than or equal to approximately 1. In some embodiments, the high thermal conductivity layer includes one or more of diamond, boron nitride, silicon carbide, beryllium oxide, boron phosphide, aluminum nitride, beryllium sulfide, boron arsenide, gallium nitride, aluminum phosphide, gallium phosphide, aluminum oxide, and graphene. In some embodiments, the method further includes forming a second ILD layer over the high thermal conductivity layer; etching the second ILD layer to form a second interconnect opening extending through the second ILD layer and the high thermal conductivity layer; and forming a second conductive interconnect within the second interconnect opening. In some embodiments, the second ILD layer is etched using one or more etchants that have a high etching selectivity between the second ILD layer and the high thermal conductivity layer. In some embodiments, the high thermal conductivity layer is formed by a deposition process performed at a temperature of less than or equal to approximately 450° C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-20. (canceled)

21. An integrated chip structure, comprising:
a plurality of conductive interconnects arranged within a dielectric structure comprising a plurality of inter-level dielectric (ILD) layers stacked onto one another over a substrate, wherein the plurality of conductive interconnects comprise interconnect vias and interconnect wires;
a plurality of heat transfer layers sandwiched between neighboring ones of the plurality of ILD layers; and
a heat pipe vertically extending through the plurality of ILD layers and intersecting the plurality of heat transfer layers, wherein the heat pipe comprises a sidewall that vertically extends past the interconnect vias and the interconnect wires.

22. The integrated chip structure of claim 21, wherein the plurality of heat transfer layers are arranged along upper surfaces of the interconnect wires.

23. The integrated chip structure of claim 21, further comprising:
a second heat pipe vertically extending through the plurality of ILD layers and intersecting one or more of the plurality of heat transfer layers, wherein the second heat pipe has a different height than the heat pipe.

24. The integrated chip structure of claim 21, wherein the heat pipe is laterally separated from the plurality of conductive interconnects by the dielectric structure.

25. The integrated chip structure of claim 21,
wherein the plurality of conductive interconnects comprise a first interconnect wire and a second interconnect wire separated by a first interconnect via; and
wherein the first interconnect wire and the second interconnect wire are vertically between the substrate and a closest one of the plurality of heat transfer layers to the substrate.

26. The integrated chip structure of claim 21, wherein the dielectric structure covers a bottommost surface of the heat pipe that faces the substrate.

27. The integrated chip structure of claim 21, wherein the plurality of ILD layers are separated by a plurality of etch stop structures, the plurality of etch stop structures respectively comprising one of the plurality of heat transfer layers and one or more additional etch stop layers having a thermal conductivity lower than the plurality of heat transfer layers.

28. The integrated chip structure of claim 21, wherein the heat pipe vertically extends to within the substrate.

29. The integrated chip structure of claim 21, further comprising:
an etch stop layer sandwiched between one of the plurality of heat transfer layers and one of the neighboring ones of the plurality of ILD layers.

30. An integrated chip structure, comprising:
a plurality of conductive features arranged within a dielectric structure on a substrate;
one or more heat transfer layers laterally extending through the dielectric structure, wherein one or more of the plurality of conductive features vertically extend through the one or more heat transfer layers; and
one or more heat transfer pipes vertically extending through the dielectric structure and intersecting the one or more heat transfer layers.

31. The integrated chip structure of claim 30, wherein the plurality of conductive features comprise a plurality of interconnect vias vertically interleaved with a plurality of interconnect wires.

32. The integrated chip structure of claim 30, wherein the one or more heat transfer layers comprise a plurality of heat transfer layers laterally extending through the dielectric structure at different heights over the substrate, one or more of the plurality of conductive features vertically extend through respective ones of the plurality of heat transfer layers.

33. The integrated chip structure of claim 30, further comprising:
an etch stop layer laterally extending through the dielectric structure and contacting one of the one or more heat transfer layers.

34. The integrated chip structure of claim 30,
wherein the plurality of conductive features comprise an interconnect wire; and
wherein the one or more heat transfer layers vertically contact an upper surface of the interconnect wire and laterally extend past opposing outermost edges of the interconnect wire in a cross-sectional view.

35. The integrated chip structure of claim 30, wherein the one or more heat transfer pipes comprise:
a first heat transfer pipe vertically extending through the dielectric structure and the one or more heat transfer layers; and
a second heat transfer pipe vertically extending through the dielectric structure and the one or more heat transfer layers, wherein the plurality of conductive features comprise a first interconnect wire that is laterally separated from the first heat transfer pipe by the dielectric structure and that is vertically above a top of the second heat transfer pipe.

36. The integrated chip structure of claim 30, wherein the plurality of conductive features comprise redistribution layers coupled to one or more conductive bonding structures.

37. The integrated chip structure of claim 30, wherein the one or more heat transfer layers laterally extend past a plurality of separate integrated chip dies.

38. An integrated chip structure, comprising:
a plurality of conductive interconnects arranged within a dielectric structure comprising a plurality of inter-level dielectric (ILD) layers stacked onto one another over a substrate, wherein the plurality of conductive interconnects comprise interconnect vias and interconnect wires; and
a heat transfer grid extending through the dielectric structure along a first direction and along a second direction that is perpendicular to the first direction in a cross-sectional view, wherein the plurality of conductive interconnects intersect the heat transfer grid.

39. The integrated chip structure of claim 38, wherein the heat transfer grid comprises:
a plurality of high thermal conductivity layers laterally extending through the dielectric structure; and
a plurality of heat transfer pipes vertically extending through the dielectric structure and intersecting the plurality of high thermal conductivity layers, wherein the plurality of heat transfer pipes comprise a sidewall that vertically extends past the interconnect vias and the interconnect wires.

40. The integrated chip structure of claim 39, wherein the plurality of heat transfer pipes respectively have a bottommost surface that is vertically offset from a surface of the dielectric structure by a non-zero distance.
